(19) United States
(12) Patent Application Publication
(10) Pub. No.: US 2024/0099116 A1
(43) Pub. Date: Mar. 21, 2024

(54) Method for preparing perovskite crystal, perovskite crystal prepared therefrom, light absorption layer, and photovoltaic cellshielding electromagnetic wave, and electrode

(71) Applicants: University-Industry Cooperation Group of Kyung Hee University, Yongin-si (KR); Korea University Research and Business Foundation, Seoul (KR)

(72) Inventors: Woo Sik Kim, Suwon-si (KR); Sang Hyuk Im, Hwaseong-si (KR); Tarak Nath Mandal, Yongin-si (KR); Jin Hyuck Heo, Suwon-si (KR)

(21) Appl. No.: 18/368,633

(22) Filed: Sep. 15, 2023

(30) Foreign Application Priority Data
Sep. 15, 2022 (KR) 10-2022-0116366

(51) Int. Cl. H10K 71/15; H01G 9/00; H01G 9/20; H10K 30/30; H10K 30/40

(52) U.S. Cl. CPC H10K 71/15; H01G 9/0036; H01G 9/2009; H10K 30/353; H10K 30/40; H10K 85/50

(57) ABSTRACT

Provided is a method for preparing a perovskite crystal that improves the performance of a photovoltaic cell. One embodiment of the present disclosure provides a method for preparing a perovskite crystal, the method including: a step S1 of preparing a perovskite solution containing a perovskite precursor and a first polar aprotic solvent; and a step S2 of preparing a perovskite crystal by mixing the perovskite solution and an antisolvent, wherein the antisolvent includes a second polar aprotic solvent.

### CROSS-REFERENCE TO RELATED APPLICATION

The present application claims priority to Korean Patent Application No. 10-2022-0116366, filed in the Korean Intellectual Property Office on Sep. 15, 2022, the entire contents of which are incorporated herein by reference.

### TECHNICAL FIELD

The present disclosure relates to a method for preparing a perovskite crystal, and more particularly, to a method for preparing a perovskite crystal, a perovskite crystal prepared therefrom, a light absorption layer, and a photovoltaic cell.

### BACKGROUND

Since perovskite absorbs a wide range of wavelengths including the visible ray region, allows formed electrons and holes to move very fast, and has high external quantum efficiency (EQE), perovskite is in the limelight as a material for high-efficiency thin-film photovoltaic cells.

In general, a light absorption layer made of a perovskite crystal has been prepared using a solvent process. As an example, a method of preparing a thin film by preparing a perovskite solution containing FAPbI₃, as FAI and PbI₂, using a solvent, and then spin-coating the perovskite solution on a substrate or the like, and evaporating the solvent at high temperatures has been used in commercially available perovskite crystals.

However, a perovskite crystal prepared by such a process has problems in that the performance of the photovoltaic cell is deteriorated due to the formation of a phase inactivated by light, or the perovskite crystal contains impurities, thereby adversely affecting the performance of the thin film.

### SUMMARY

An object of the present disclosure is to provide a method for preparing a perovskite crystal capable of preparing a single crystal of high crystallization and high purity.

Another object of the present disclosure is to provide a method for preparing a perovskite crystal having structural stability and phase stability for a long period of time even under conditions of high relative humidity.

Another object of the present disclosure is to provide a method for preparing a perovskite crystal that improves the performance of a photovoltaic cell.

Another object of the present disclosure is to provide a perovskite crystal prepared by the method for preparing a perovskite crystal.

Another object of the present disclosure is to provide a light absorption layer made of the perovskite crystal.

Another object of the present disclosure is to provide a photovoltaic cell including the light absorption layer.

The objects of the present disclosure are not limited to the objects mentioned above, and other objects and advantages of the present disclosure not mentioned above can be understood by the following description and will be more clearly understood by embodiments of the present disclosure. It will also be readily apparent that the objects and advantages of the present disclosure may be realized by means of the instrumentalities and combinations indicated in the claims.

One embodiment of the present disclosure for achieving the above object is to provide a method for preparing a perovskite crystal, the method including: a step S1 of preparing a perovskite solution containing a perovskite precursor and a first polar aprotic solvent; and a step S2 of preparing a perovskite crystal by mixing the perovskite solution and an antisolvent, wherein the antisolvent includes a second polar aprotic solvent.

Another embodiment of the present disclosure for achieving the above object is to provide a perovskite crystal prepared by the method for preparing a perovskite crystal.

Another embodiment of the present disclosure for achieving the above object is to provide a light absorption layer made of the perovskite crystal.

Another embodiment of the present disclosure for achieving the above object is to provide a photovoltaic cell including the light absorption layer.

The solution means to the above problems do not enumerate all the features of the present disclosure. Various features of the present disclosure and the advantages and effects according thereto will be understood in more detail with reference to the following specific embodiments.

According to one embodiment of the present disclosure, a perovskite crystal having a single crystal structure of high crystallization and high purity can be prepared, and a perovskite crystal having structural stability and phase stability for a long period of time can be prepared even under conditions of high relative humidity. When such a perovskite crystal is applied to the light absorption layer of a photovoltaic cell, the fill factor corresponding to the power conversion efficiency and power generation quality of the photovoltaic cell can be simultaneously increased.

The specific effects of the present disclosure in addition to the above-described effects will be described together while explaining the following specific details for carrying out the present disclosure.

### BRIEF DESCRIPTION OF THE DRAWINGS

FIG. 1 is a schematic diagram of a method for preparing a perovskite crystal according to one embodiment of the present disclosure.

FIG. 2A shows dielectric constants and relative polarities according to the types of an antisolvent.

FIG. 2B is X-ray diffraction (XRD) analysis results of a crystal according to Example 1 and crystals according to Comparative Examples 1 to 4.

FIG. 2C is an XRD analysis result of δ-FAPbI₃ which is a single crystal compatible with a product according to Example 1.

FIG. 2D is a graph comparing XRD analysis results of the product according to Example 1 and PbI₂.

FIG. 3A is field emission scanning electron microscope (FE-SEM) images of products produced by the methods according to Comparative Examples 1 to 4 (I to IV) and Example 1 (V), and an FE-SEM image of PbI₂ (VI).

FIG. 3B is FE-SEM images of a product (δ-FAPbI₃) produced by the method according to Example 1.

FIG. 4 shows the solubility (g/ml) of FAPbI₃ according to the volume content of acetonitrile.

FIG. 5 is a result of Fourier Transform Infrared (FT-IR) spectroscopy analysis of the product (δ-FAPbI₃) according to Example 1.

FIG. 6 is results of Thermogravimetric analysis (TGA) and Derivative thermogravimetric (DTG) analysis of the product (δ-FAPbI₃) according to Example 1.

FIG. 7A is an X-ray photoelectron spectroscopy (XPS) analysis result of the product (δ-FAPbI₃) according to Example 1.

FIG. 7B shows a Pb 4f peak of the product (δ-FAPbI₃) according to Example 1.

FIG. 7C shows an I 3d peak of the product (δ-FAPbI₃) according to Example 1.

FIG. 8 is a Scanning Electron Microscope-Energy Dispersive X-ray Spectrometer (SEM-EDS) analysis result of the product (δ-FAPbI₃) according to Example 1.

FIG. 9 is an analysis result of UV-visible spectrometry of the product according to Example 1.

FIG. 10 is a Raman spectroscopy analysis result of the product according to Example 1.

FIG. 11A is XRD analysis results of the product (δ-FAPbI3) according to Example 1 depending on the passage of a long period of time under conditions of 25° C. and 74% relative humidity (RH).

FIG. 11B is a digital photograph (I) and an SEM photograph (II) of the product according to Example 1 depending on the passage of a long period of time under conditions of 25° C. and 74% relative humidity (RH).

FIG. 12A is a current density-voltage graph (J-V curve) of photovoltaic cells according to Example 2 and Comparative Example 5.

FIG. 12B is External Quantum Efficiencies (EQE) of the photovoltaic cells according to Example 2 and Comparative Example 5.

FIG. 12C is short circuit current densities (J_{sc}, mA/cm²) of the photovoltaic cells prepared by methods of Example 2 and Comparative Example 5 according to light intensity (mW/cm²).

FIG. 12D is open-circuit voltages (V_{oc}, V) of the photovoltaic cells prepared by the methods of Example 2 and Comparative Example 5 according to light intensity (mW/cm²).

FIG. 12E is electroluminescence external quantum efficiencies (EQE_{EL}) of a photovoltaic cell according to current densities.

FIG. 12F is results of a space charge limited current (SCLC) analysis method of the photovoltaic cells prepared by the methods of Example 2 and Comparative Example 5.

### DETAILED DESCRIPTION

Hereinafter, each configuration of the present disclosure will be described in more detail so that those skilled in the art to which the present disclosure pertains can easily practice it, but this is only one example, and the scope of rights of the present disclosure is not limited by the following content.

One embodiment of the present disclosure provides a method for preparing a perovskite crystal, the method including: a step S1 of preparing a perovskite solution containing a perovskite precursor and a first polar aprotic solvent; and a step S2 of preparing a perovskite crystal by mixing the perovskite solution and an antisolvent, wherein the antisolvent includes a second polar aprotic solvent. A perovskite crystal prepared by a method for preparing a conventionally commercially available perovskite crystal has had a problem in that a crystal having low purity and low crystallinity is obtained since impurities are contained. There is a negative effect on the performance of the light absorption layer due to this, and there has been a problem in that a decrease in the performance of the photovoltaic cell occurs due to the formation of a phase inactivated by light. According to one aspect of the present disclosure, after preparing a perovskite solution containing a perovskite precursor and a first polar aprotic solvent, antisolvent crystallization is induced by selecting a second polar aprotic solvent so that a perovskite crystal of high purity and high crystallization may be prepared. According to another aspect of the present disclosure, a perovskite crystal having structural stability and phase stability for a long period of time may be prepared even under conditions of high relative humidity. When such a perovskite crystal is applied to the light absorption layer of a photovoltaic cell, the fill factor corresponding to the power conversion efficiency and power generation quality of the photovoltaic cell may be simultaneously increased.

Hereinafter, the configuration of the present disclosure will be described in more detail.

1. Method for Preparing Perovskite Crystal and Perovskite Crystal Prepared Therefrom

A method for preparing a perovskite crystal according to the present disclosure includes a step S1 of preparing a perovskite solution containing a perovskite precursor and a first polar aprotic solvent. For example, in the step S1, the perovskite precursor may include two or more types of reactants, and may be reactants including formamidinium (FA)I and PbI₂. For example, FAI and PbI₂ may react with each other to synthesize FAPbI₃ and may be included in the perovskite solution.

The first polar aprotic solvent according to the present disclosure may serve as a solvent for dissolving the perovskite precursor.

Specifically, the first polar aprotic solvent may be a solvent having a dielectric constant of 32 to 40 and a relative polarity of 0.35 to 0.45 based on water having a relative polarity of 1.0, more specifically a solvent having a dielectric constant of 34 to 40 and a relative polarity of 0.36 to 0.43 based on water having a relative polarity of 1.0, or more specifically a solvent having a dielectric constant of 35 to 39 and a relative polarity of 0.37 to 0.42 based on water having a relative polarity of 1.0, and more specifically it may include dimethylformamide (DMF).

The step S1 may be a step necessary for the perovskite precursor including two or more types of reactants to react with each other and precipitate into a crystal. However, the crystal precipitated through the step S1 has had a problem in that it contains impurities to not only have low purity, but also form a phase deactivated by light.

Accordingly, the method for preparing a perovskite crystal according to the present disclosure includes a step S2 of preparing a perovskite crystal by mixing the perovskite solution and an antisolvent. Specifically, the step S2 may be a step of precipitating a solid phase crystal from a flowable medium that is a resulting product of the step S1 proceeding as a liquid-liquid reaction. The step S2 may be a step which can remarkably lower the impurities contained in the perovskite crystal and which is required for inducing a high-purity perovskite crystal.

An antisolvent according to the present disclosure may include a second polar aprotic solvent. Specifically, the second polar aprotic solvent may provide a driving force for inducing a change in solubility by changing the concentration of a stable perovskite solution to the equilibrium concentration or more, and may be specifically a solvent which is used to use the antisolvent crystallization step.

According to one embodiment of the present disclosure, the antisolvent may have a dielectric constant of 16 or more, specifically 24 or more, more specifically 28 or more, and more specifically 32 to 40. When the dielectric constant of the antisolvent satisfies within the above-described numerical range, the antisolvent crystallization step proceeds smoothly, and thus a high-purity perovskite crystal may be precipitated.

According to another embodiment of the present disclosure, the antisolvent may have a relative polarity of more than 0.4 and 0.6 or less based on water having a relative polarity of 1.0, specifically a relative polarity of more than 0.4 and 0.5 or less based on water having a relative polarity of 1.0. When the relative polarity of the antisolvent satisfies within the above-described numerical value range, the antisolvent crystallization step proceeds smoothly, and thus a high-purity perovskite crystal may be precipitated. For example, the antisolvent may include acetonitrile (CH₃CN).

The perovskite crystal according to the present disclosure may be a compound represented by General Formula 1 below.

AₐB_{b}X_{c} [General Formula 1]

In General Formula 1, A is a monovalent organic cation or a monovalent metal cation, B is a divalent or trivalent metal cation, X is a monovalent anion, and a, b, and c are all natural numbers, and satisfy a+2b=c or a+3b=4c.

According to one example, when a+2b=c is satisfied, A may be formamidinium (FA) or methylammonium (MA), B may be any one of Pb, Sn, Ti, Nb, Zr, and Ce, and X may be a halogen element. Specifically, the perovskite crystal may be δ-FAPbI₃.

Another embodiment of the present disclosure may provide a perovskite crystal prepared by a method for preparing a perovskite crystal. The perovskite crystal is a crystal from which impurities are excluded, and may be in a high purity state. Accordingly, a light absorption layer made of a high-purity perovskite crystal is applied to a photovoltaic cell device, and thus performance such as a fill factor and a power conversion efficiency of the photovoltaic cell may be improved.

Specifically, the perovskite crystal may be a single crystal of a delta phase (6-Phase). A single crystal is a structure in which atoms are arranged by having regularity in a solid, and means a crystal in which the entire solid mass has the same regularity.

The perovskite crystal according to the present disclosure may have a hexagonal rod shape. Specifically, the perovskite crystal may have a length of 800 to 1,500 μm and a diameter of 50 to 70 μm. When the length and diameter of the perovskite crystals are within the above-described numerical range, the perovskite crystal may be effectively dispersed in a composition for forming a light absorption layer and the coatability of the composition for forming the light absorption layer may be advantageous.

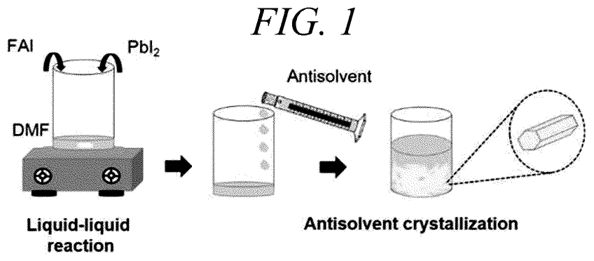

Hereinafter, the configuration of the present disclosure will be described in more detail with reference to FIG. 1.

FIG. 1 is a schematic diagram of a method for preparing a perovskite crystal according to one embodiment of the present disclosure.

Referring to FIG. 1, the method for preparing a perovskite crystal according to one embodiment of the present disclosure may include the steps of: dissolving a perovskite precursor (FAI and PbI₂) in a solvent (DMF), and then inducing a liquid-liquid reaction to prepare a perovskite solution containing FAPbI₃; and preparing a perovskite crystal having a hexagonal rod shape by adding an antisolvent to the perovskite solution.

2. Light Absorption Layer and Photovoltaic Cell Including the Same

Another embodiment of the present disclosure may provide a light absorption layer made of the perovskite crystal. The light absorption layer may generate electron-hole pairs by absorbing light energy. The light absorption layer may have a thickness of, for example, 50 to 500 nm.

According to another embodiment of the present disclosure, the composition for forming the light absorption layer may include the perovskite crystal and a mixed solvent. The mixed solvent is not particularly limited, but may be, for example, a mixed solvent in which dimethylformamide (DMF) and dimethyl sulfoxide (DMSO) are mixed.

Another embodiment of the present disclosure may provide a photovoltaic cell including: a first electrode; a second electrode; and the light absorption layer disposed between the first and second electrodes.

According to one embodiment of the present disclosure, the light absorption layer may include one or more layers. For example, the light absorption layer may be a single-layer structure or a multi-layer structure of two or more layers.

In the first electrode according to the present disclosure, holes generated in the light absorption layer by light energy may be moved to a conducting wire to allow current to flow. For example, the first electrode may be a metal oxide-based transparent electrode such as indium tin oxide (ITO), fluoride-doped tin oxide (FTO), zinc oxide (ZnO), indium zinc oxide (IZO), or Al-doped zinc oxide (AZO). At this time, the first electrode may be formed on one surface of a transparent substrate, and the transparent substrate may be: glass; or a polymer substrate having high light transmittance such as polyethylene terephthalate (PET), polystyrene (PS), polycarbonate (PC), polymethyl methacrylate (PMMA), polyimide (PI), and the like. The first electrode may have a thickness of, for example, 50 to 500 nm.

The second electrode according to the present disclosure may cause current to flow by moving electrons generated in the light absorption layer by light energy to a conducting wire. For example, the second electrode may include any one or two or more selected from the group consisting of aluminum (Al), gold (Au), silver (Ag), copper (Cu), carbon (C), carbon nanotube, conductive polymer, etc. The second electrode may have a thickness of, for example, 50 to 500 nm.

The photovoltaic cell according to another embodiment of the present disclosure may further include a hole transport layer disposed between the first electrode and the light absorption layer, and an electron transport layer disposed between the second electrode and the light absorption layer.

The hole transport layer according to the present disclosure may move holes generated by light energy from the light absorption layer to the first electrode. The hole transport layer may be used without particular limitation as long as it is commonly used in the art, and specific examples thereof may include any one or two or more selected from the group consisting of poly(triarylamine) (PTAA), 2,2′,7,7′-tetrakis-(N,N-di-4-methoxyphenylamino)-9,9′-spirobifluorene (Spiro-OMeTAD), poly(3,4-ethylenedioxythiophene):poly(4-styrene sulfonate) (PEDOT:PSS), poly(3,4-ethylenedioxythiophene):poly(4-styrene sulfonate):polyglycol(glycerol) (G-PEDOT), poly(aniline):poly(4-styrene sulfonate) (PANI:PSS), poly(aniline):camphor sulfonic acid (PANI:CSA), poly(4,4′-dimethoxy bithophene) (PDBT), poly(3-hexylthiophene) (P3HT), poly [2,6-(4,4-bis-(2-ethylhexyl)-4H-cyclopenta12,1-b;3,4-111 dithiophene)-alt-4,7-(2,1,3-benzothiadiazole)] (PCPDTBT), poly[N-9″-heptadecanyl-2,7-carbazole-alt-5,544′,7′-di-2-thienyl-T,F,3′-benzothiadiazole)] (PCDTBT), and the like. The hole transport layer may have a thickness of, for example, 10 to 600 nm.

The electron transport layer according to the present disclosure may move electrons generated by light energy from the light absorption layer to the second electrode. The electron transport layer may further include, for example, fullerene (C₆₀), (6,6)-phenyl-C₆₁-butyric acid methyl ester (PCBM), which is designed so that fullerene is well dissolved in an organic solvent, (6,6)-phenyl-C70-butyric acid methyl ester (PC70BM), or the like, and in addition, it may also include, as single molecules, perylene, polybenzimidazole (PBI), (3,4,9,10-perylene-tetracarboxylic bisbenzimidazole (PTCBI), etc. The electron transport layer may have a thickness of, for example, 10 to 600 nm.

A photovoltaic cell according to another embodiment of the present disclosure may further include a hole blocking layer disposed between the second electrode and the electron transport layer. The hole blocking layer may improve the performance of a photovoltaic cell by performing a blocking role of blocking the movement of holes. For example, the hole blocking layer may include at least one selected from 1,4,5,8-naphthalene tetracarboxylic dianhydride (NTCDA), bathocuproine (BCP), tris [3-(3-pyridyl)-mesityl]borane (3TPYMB), LiF, Alq₃, Gaq₃, Inq₃, Znq₂, Zn(BTZ)₂, BeBq₂, and combinations thereof, but is not limited to. The hole blocking layer may have a thickness of, for example, 10 to 600 nm.

According to one embodiment of the present disclosure, it can be confirmed that both the fill factor (FF) and the power conversion efficiency (PCE) are increased by implementing the light absorption layer with the perovskite crystal. That is, according to one embodiment of the present disclosure, the output energy for light energy incident from the sun can be inferred to be increased, and the power generation quality can also be inferred to be increased.

3. Applications of Photovoltaic Cell

Another embodiment of the present disclosure may provide a photovoltaic cell module including the photovoltaic cell. The photovoltaic cell module may be widely applied to, for example, a photovoltaic power generation system, a photovoltaic building, a photovoltaic vehicle, a photovoltaic satellite, and a traffic signal.

Hereinafter, Examples of the present disclosure will be described in detail so that those skilled in the art to which the present disclosure pertains can easily practice it, but this is only one example, and the scope of rights of the present disclosure is not limited by the following content.

### Preparation Example 1: Preparation of Crystal Using Antisolvent

### Example 1: Preparation of δ-FAPbI₃ Single Crystal Using Antisolvent (CH₃CN)

After adding both PbI₂ (461 mg, 1 mmol) and FAI (172 mg, 1 mmol) to dimethylformamide (DMF) (1 ml), the mixture was constantly stirred in a magnetic stirrer until both PbI₂ and FAI were dissolved. After completely dissolving all materials, a yellow perovskite solution was prepared. The yellow perovskite solution was filtered with a PTFE-H filter (0.2 μm) to obtain a transparent perovskite solution. After slowly adding an excessive amount of acetonitrile (CH₃CN) to the transparent perovskite solution, an antisolvent crystallization reaction was induced for 24 hours. Thereafter, yellow rod-shaped crystals were filtered and then washed with diethyl ether. The washed crystals were dried under vacuum for 12 hours to finally synthesize δ-FAPbI3 single crystals.

### Comparative Example 1: When Using Diethyl Ether Unlike in Example 1

A powder was prepared using the same manner as in Example 1 except that diethyl ether (DE), an aprotic solvent, was used instead of acetonitrile (CH₃CN).

### Comparative Example 2: When Using Chloroform Unlike in Example 1

A powder was prepared using the same manner as in Example 1 except that chloroform (CHCl₃), an aprotic solvent, was used instead of acetonitrile (CH₃CN).

### Comparative Example 3: When Using Methanol Unlike in Example 1

A powder was prepared using the same manner as in Example 1 except that methanol (MeOH), a polar protic solvent, was used instead of acetonitrile (CH₃CN).

### Comparative Example 4: When Using Ethanol Unlike in Example 1

A powder was prepared using the same method as in Example 1 except that ethanol (EtOH), a polar protic solvent, was used instead of acetonitrile (CH₃CN).

### Experimental Example 1: XRD Analysis of Product Produced by Method According to Preparation Example 1

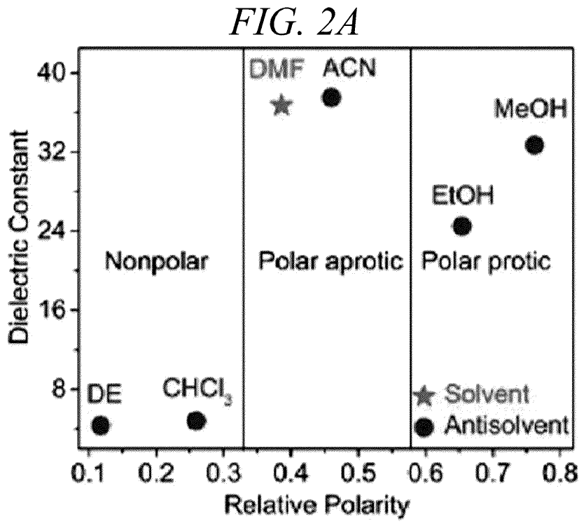

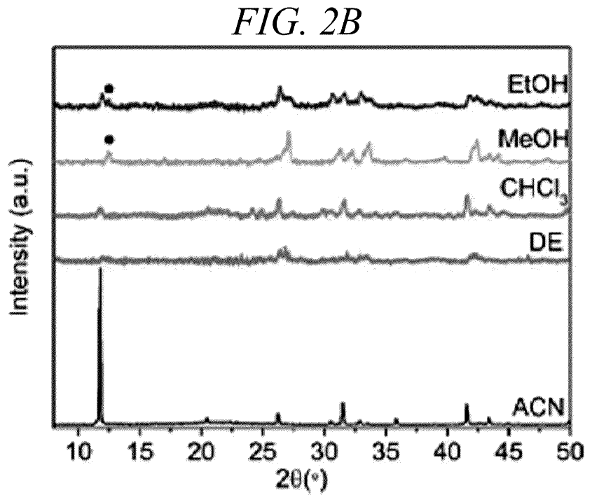

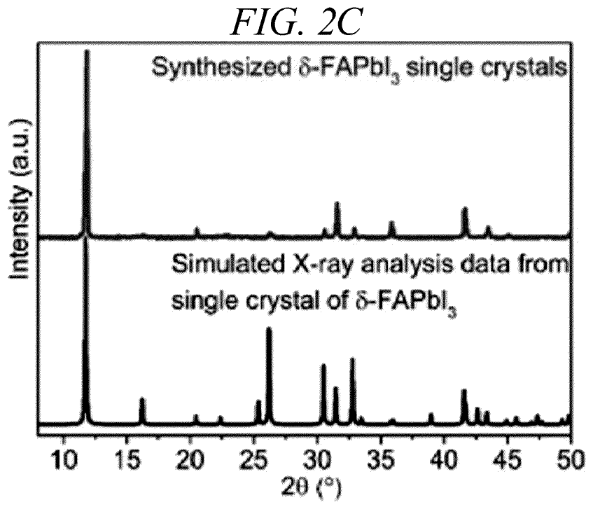

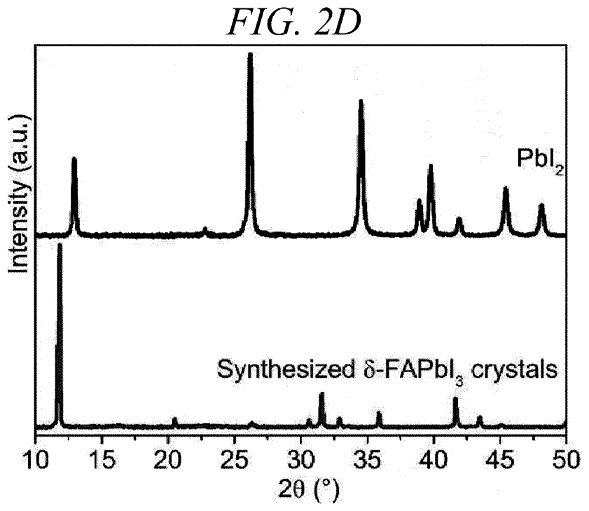

FIG. 2A shows dielectric constants and relative polarities according to the types of an antisolvent.

FIG. 2B is X-ray diffraction (XRD) analysis results of a crystal according to Example 1 and crystals according to Comparative Examples 1 to 4. The XRD analysis results were analyzed using Mo K Bruker APEX-II CCD equipment under conditions of 296K, Mo Kα radiation (λ=0.71073).

Referring to FIGS. 2A and 2B, it can be confirmed that a perovskite single crystal (δ-FAPbI₃) with a vivid peak corresponding to the delta (δ) phase was synthesized by using acetonitrile (ACN), which is a polar aprotic solvent as an antisolvent. On the other hand, black dots in FIG. 2B mean (001) diffraction peaks by PbI₂.

FIG. 2C is an XRD analysis result of δ-FAPbI₃ which is a single crystal compatible with a product according to Example 1.

FIG. 2D is a graph comparing XRD analysis results of the product according to Example 1 and PbI₂.

Referring to FIG. 2C, it can be reconfirmed that the product according to Example 1 is δ-FAPbI₃ of a single crystal, and referring to FIG. 2D, since the product according to Example 1 does not show a peak corresponding to PbI₂, it can be confirmed that the product according to Example 1 is a product synthesized to high purity.

### Experimental Example 2: FE-SEM Images of Product According to Preparation Example 1

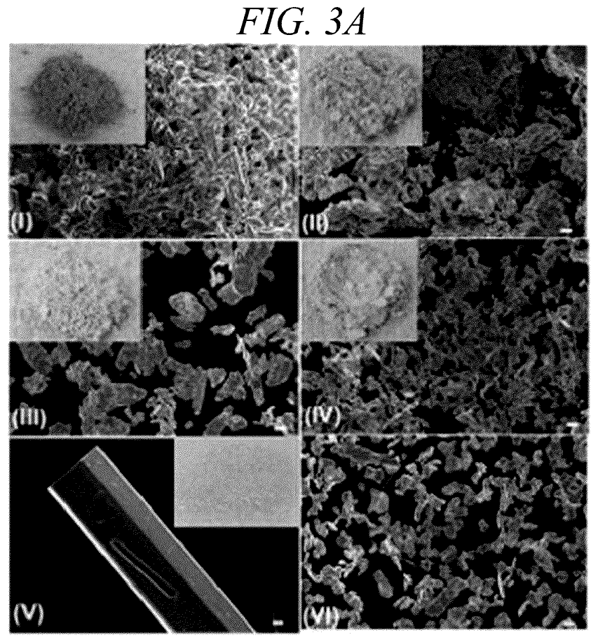

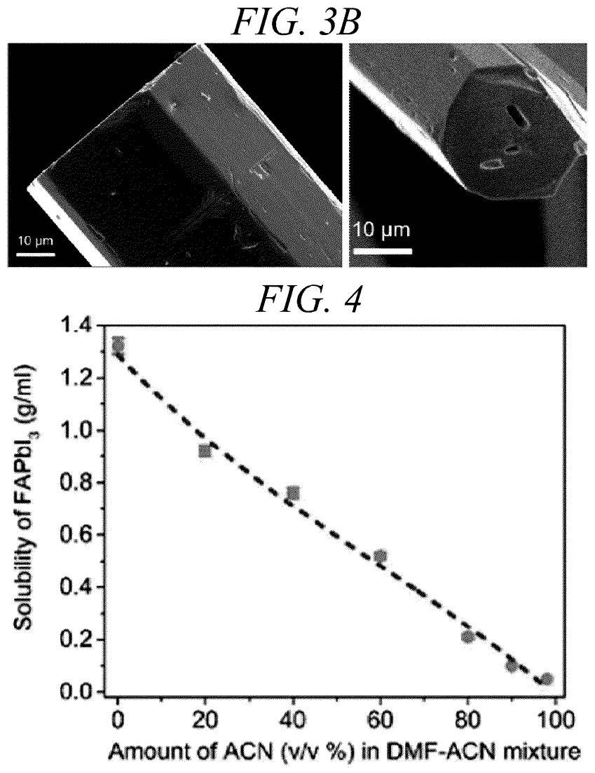

FIG. 3A is field emission scanning electron microscope (FE-SEM) images of products produced by the methods according to Comparative Examples 1 to 4 (I to IV) and Example 1 (V), and an FE-SEM image of PbI₂ (VI).

FIG. 3B is FE-SEM images of a product (δ-FAPbI₃) produced by the method according to Example 1.

Referring to FIGS. 3A and 3B, it can be confirmed that the product produced by the method according to Example 1 is larger in size than the products produced by the methods according to Comparative Examples 1 to 4 and has a hexagonal rod shape. Specifically, it can be confirmed that the product produced by the method according to Example 1 has a diameter of 50 to 70 μm and a length of about 1,000 μm. It can be inferred through this that high-yield single-crystal perovskite crystals may be synthesized by using a polar aprotic solvent as an antisolvent.

### Experimental Example 3: Measurement of Solubility of 45-FAPbI₃ According to Content of ACN

FIG. 4 shows the solubility (g/ml) of FAPbI₃ according to the volume content of acetonitrile.

Referring to FIG. 4, it can be confirmed that a tendency of decreasing the solubility of δ-FAPbI₃ is shown as the volume content of acetonitrile increases based on the total volume of the mixed solvent in which DMF and acetonitrile (ACN) that dissolve the perovskite precursor (PbI₂ and FAI) are mixed.

### Experimental Example 4: FT-IR Analysis of Product (45-FAPbI₃) According to Example 1

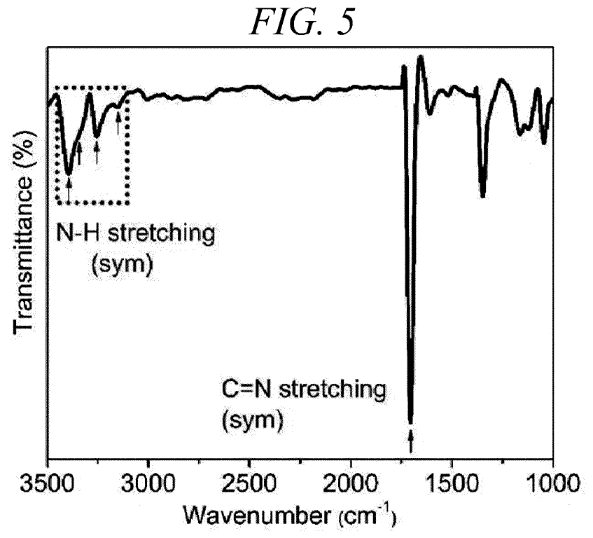

FIG. 5 is a result of Fourier Transform Infrared (FT-IR) spectroscopy analysis of the product (δ-FAPbI₃) according to Example 1.

Referring to FIG. 5, it can be confirmed that the characteristic peaks of N—H bonds in the FA⁺ ion appear at 3,400, 3,352, 3,270, and 3,165 cm⁻¹. Through this, it can be confirmed that a strong H-bond bond is formed with N—H derived from the strong FA⁺ ion and I⁻ derived from PbI₆⁴⁻, and it can be confirmed that a peak corresponding to the symmetric stretching vibration of C═N appears at 1,710 cm⁻¹.

### Experimental Example 5: TGA and DTG Analysis of Product (δ-FAPbI₃) According to Example 1

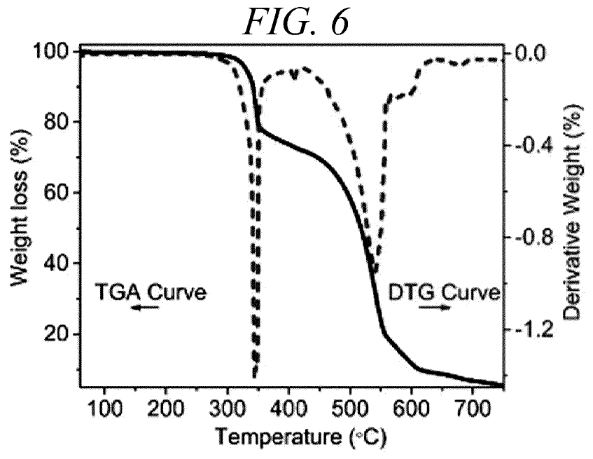

FIG. 6 is results of Thermogravimetric analysis (TGA) and Derivative thermogravimetric (DTG) analysis of the product (δ-FAPbI₃) according to Example 1. The TGA analysis was performed using a Perkin-Elmer TGA-8000 instrument, and the heating rate was maintained at 10° C./min under a nitrogen atmosphere.

Referring to FIG. 6, it can be confirmed that the product (δ-FAPbI₃) according to Example 1 is stable up to 300° C. without weight loss. Specifically, it can be confirmed that the first decomposition of the product caused a rapid weight loss of about 20% at about 300 to 350° C. due to HI, and the second decomposition occurred at 450° C. and there was a weight loss of about 7%. The second decomposition is judged to originate from formamidinium (FA).

### Experimental Example 6: Results of XPS Analysis of Product (45-FAPbI₃) According to Example 1

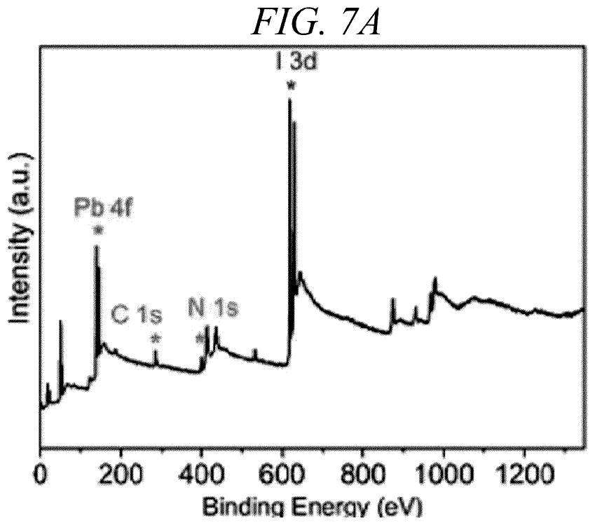

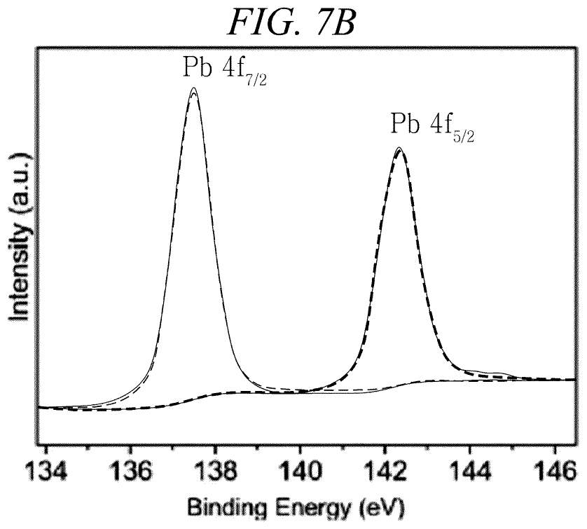

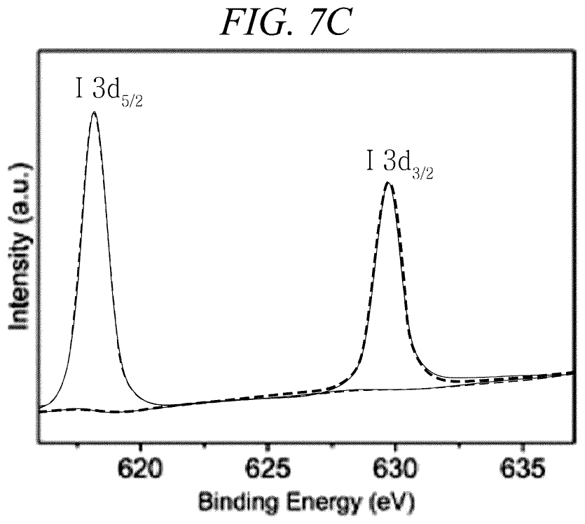

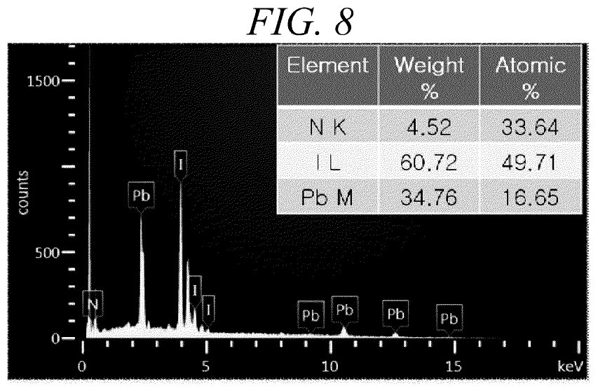

FIG. 7A is an X-ray photoelectron spectroscopy (XPS) analysis result of the product (δ-FAPbI₃) according to Example 1.

FIG. 7B shows a Pb 4f peak of the product (δ-FAPbI₃) according to Example 1.

FIG. 7C shows an I 3d peak of the product (δ-FAPbI₃) according to Example 1.

Referring to FIGS. 7A to 7C, the detected peaks are Pb 4f_{7/2} (137.5 eV), 4f_{5/2} (142.3 eV), I 3d_{5/2} (618.2 eV), and 3d_{3/2} (629.7 eV), and it can be confirmed that these peaks are originated from Pb²⁺ and I⁻, respectively.

### Experimental Example 7: SEM-EDS Analysis Result of Product (δ-FAPbI₃) According to Example 1

FIG. 8 is a Scanning Electron Microscope-Energy Dispersive X-ray Spectrometer (SEM-EDS) analysis result of the product (δ-FAPbI₃) according to Example 1.

Referring to FIG. 8, it can be confirmed that the atomic ratio of I to Pb is about 3. It can be inferred through this that high-purity FAPbI₃ was synthesized by the method according to Example 1.

### Experimental Example 8: Result of Ultraviolet-Visible Spectroscopy of Product (δ-FAPbI₃) According to Example 1

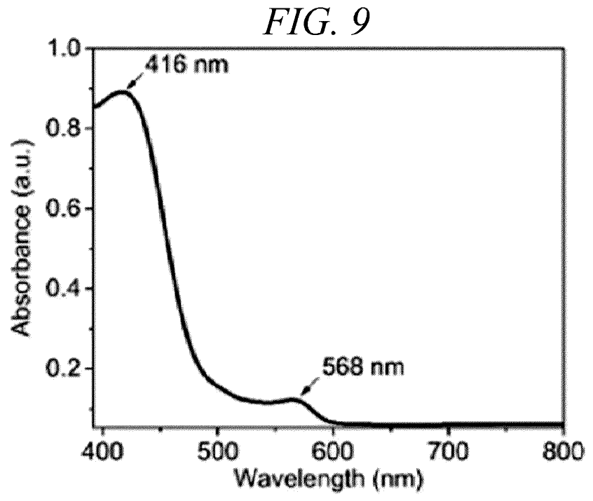

FIG. 9 is an analysis result of UV-visible spectrometry of the product according to Example 1.

Referring to FIG. 9, it can be confirmed that the product according to Example 1 exhibits characteristic peaks at 416 nm and 568 nm. It can be confirmed that such peaks coincide with the peaks of δ-FAPbI₃ disclosed in the reference (S. Ruan, D. P. McMeekin, R. Fan, N. A. S. Webster, H. Ebendorff-Heidepriem, Y.-B. Cheng, J. Lu, Y. Ruan and C. R. McNeill, The Journal of Physical Chemistry C, 2020, 124, 2265-2272).

### Experimental Example 9: Raman Spectrum Results of Product (δ-FAPbI₃) According to Example 1

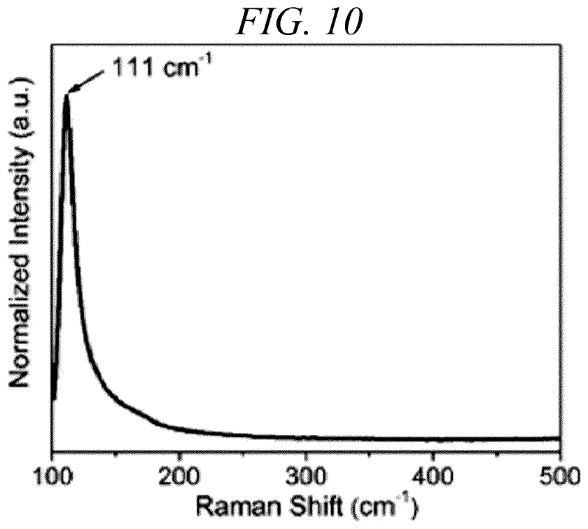

FIG. 10 is a Raman spectroscopy analysis result of the product according to Example 1.

Referring to FIG. 10, it can be confirmed that a strong Raman scattering peak appears at 111 cm⁻¹ due to in-plane bending of FA⁺ cations.

### Experimental Example 10: Stability Evaluation of Product (δ-FAPbI₃) According to Example 1

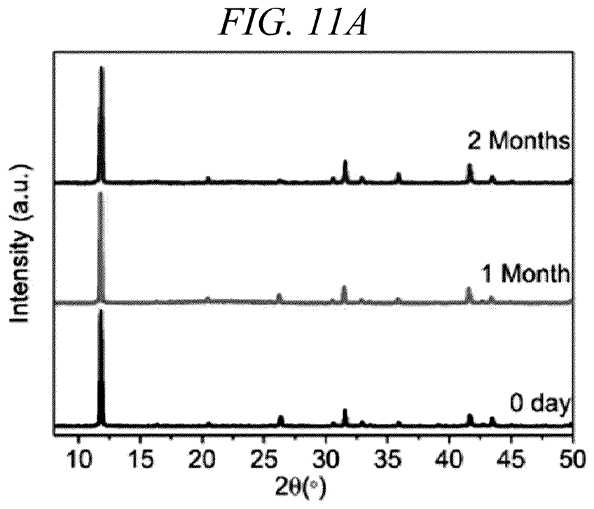

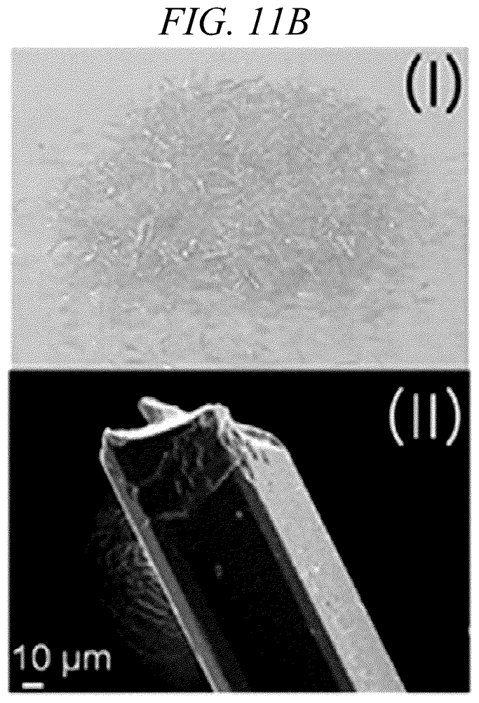

FIG. 11A is XRD analysis results of the product (δ-FAPbI₃) according to Example 1 depending on the passage of a long period of time under conditions of 25° C. and 74% relative humidity (RH).

Referring to FIG. 11A, it can be confirmed that the product (δ-FAPbI₃) according to Example 1 shows no change in the XRD peak under conditions of high relative humidity even after 2 months have elapsed. It can be inferred through this that the product prepared by the method according to Example 1 is structurally and compositionally very stable even under conditions of high relative humidity.

FIG. 11B is a digital photograph (I) and an SEM photograph (II) of the product according to Example 1 depending on the passage of a long period of time under conditions of 25° C. and 74% relative humidity (RH).

Referring to FIG. 11B, it can be confirmed that the product produced by the method according to Example 1 does not change color by showing yellow color even if 2 months have elapsed under conditions of high relative humidity, and it can be inferred that the decomposition reaction due to high humidity does not occur.

### Preparation Example 2: Preparation of Photovoltaic Cell

### Example 2: Preparing Photovoltaic Cell Using Product (δ-FAPbI₃) According to Example 1

A conductive glass coated with tin oxide doped with patterned indium (ITO-coated conductive glass; hereinafter referred to as ‘ITO substrate’) was ultrasonically cleaned in the order of deionized water, acetone, and isopropanol for 15 minutes, and then dried. The dried resulting product was treated with UV/ozone (UVO) for 20 minutes.

A polytriarylamine (PTAA) solution (5 mg/mL in toluene), a hole transport material, was applied to the ITO substrate by spin coating at 6,000 rpm for 30 seconds, and then annealed on a hot plate at 100° C. for 10 minutes to form a PTAA (EM-Index) film.

A crystal (826.8 mg; δ-FAPbI₃) produced by the method according to Example 1 and methylammonium chloride (MACl) (17.6 mg; MACl) were dissolved in a mixed solvent (1 mL) in which dimethylformamide (DMF) and dimethyl sulfoxide (DMSO) were mixed at a volume ratio of 8.5:1.5 to prepare a composition for forming a light absorption layer. The composition for forming a light absorption layer was spin-coated at 5,000 rpm for 30 seconds on one surface of the PTAA film of the ITO substrate on which the PTAA film was formed, and then the spin-coated resulting product was immersed in a water bath containing diethyl ether to form a light absorption layer.

After taking out the resulting product immersed in the water bath and annealing it at 150° C. for 45 minutes, a fullerene layer (C₆₀, 30 nm), a hole blocking layer for blocking holes (Bathocuproine; BCP, 150 nm), and an Ag electrode were sequentially stacked on one surface of the light absorption layer at 3×10⁻⁷ torr using a thermal evaporator, thereby preparing a photovoltaic cell. The photovoltaic cell is a structure composed of a cathode (ITO)/a hole transport layer (PTAA)/a light absorption layer (FAPbI₃)/an electron transport layer (C₆₀)/a hole blocking layer (BCP)/an anode (Ag).

### Comparative Example 5: Preparation of Commercial Perovskite Photovoltaic Cell

A photovoltaic cell was prepared in the same manner as in Example 2 by using a composition for forming a light absorption layer, in which FAI (224.6 mg), PbI₂ (602.2 mg), and MACl (17.6 mg) were dissolved in a mixed solvent (1 mL) in which DMF and DMSO were mixed at a volume ratio of 8.5:1.5, instead of a composition for forming a light absorption layer, which was prepared using the crystal produced by the method according to Example 1.

### Experimental Example 11: Performance Evaluation of Photovoltaic Cell

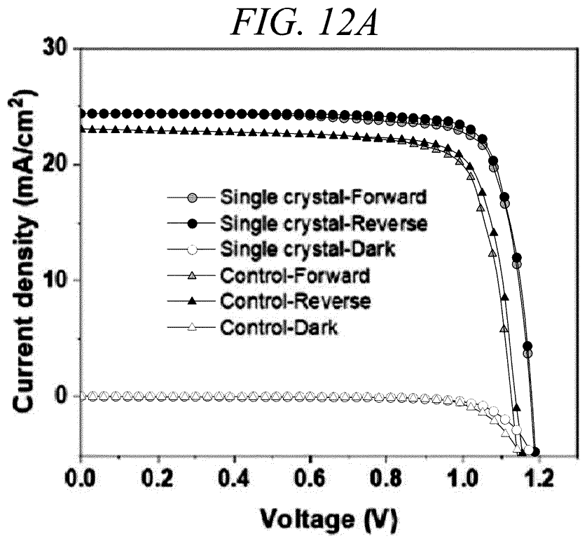

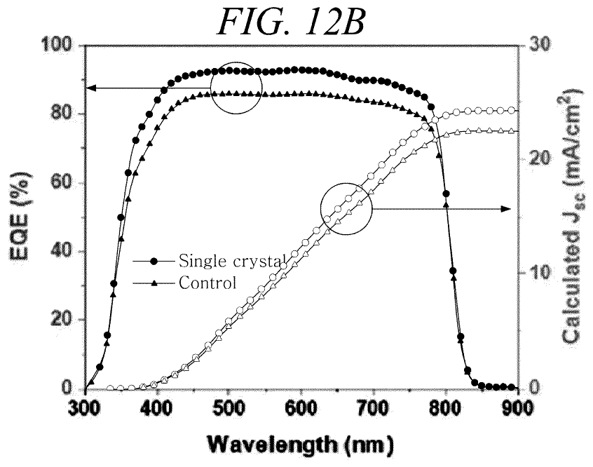

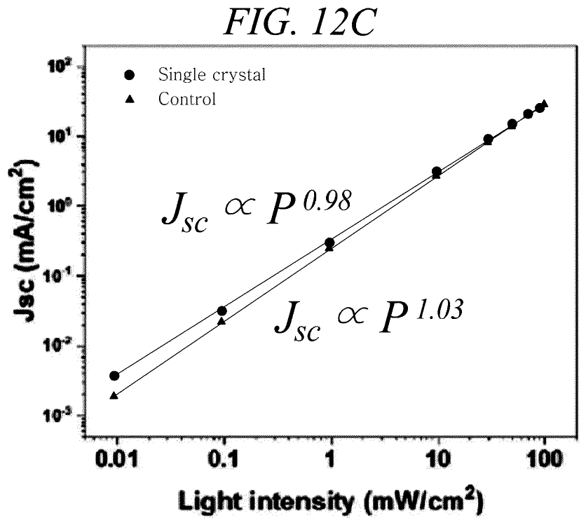

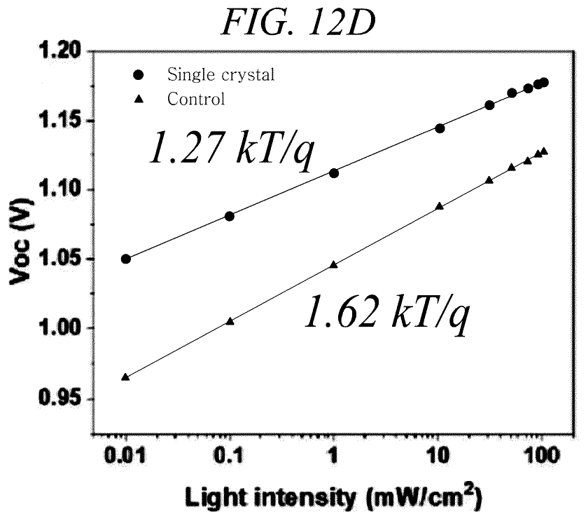

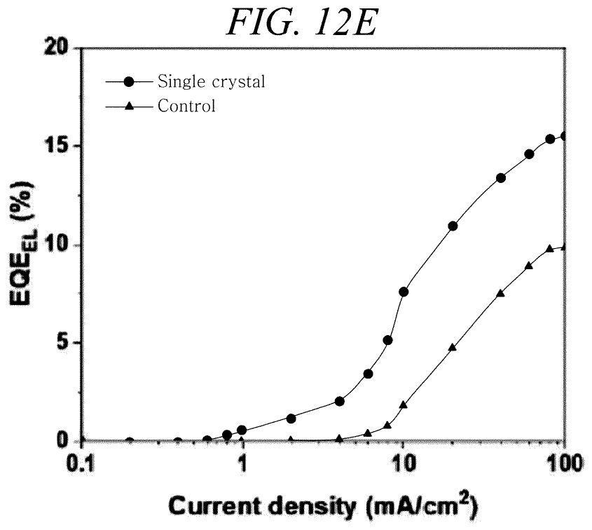

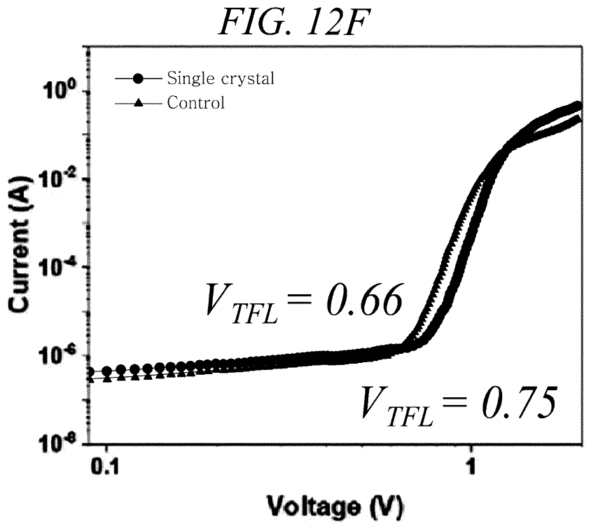

FIG. 12A is a current density-voltage graph (J-V curve) of photovoltaic cells according to Example 2 and Comparative Example 5. The change in current density was analyzed using a source meter (Keithley 2420) under the conditions of one light source (100 mW/cm² AM 1.5G) using a solar simulator (Abet Technologies' Sun 3000).

FIG. 12B is External Quantum Efficiencies (EQE) of the photovoltaic cells according to Example 2 and Comparative Example 5. The external quantum efficiency means the number of charge carriers collected by the photovoltaic cell per number of photons of light energy projected onto the photovoltaic cell from the outside, and is an index indicating the reactivity of the photovoltaic cell to a given light wavelength. The external quantum efficiencies (EQE) of the photovoltaic cells were measured using a power supply device (150 W Xenon lamp, #13014, Abet Technologies) including a monochromator (MonoRa-500i, DONGWOO OPTRON CO., LTD.) and a potentiostat (IviumStat, IVIUM).

The results of FIGS. 12A and 12B are summarized as in Table 1 below.

TABLE 1

| | Scan | | J_{sc} | | |
|---|---|---|---|---|---|
| Sample | direction | V_{oc} (V) | (mA/cm²) | FF (%) | PCE (%) |
| Example 2 | Forward | 1.17 | 24.42 | 80.51 | 23.00 |
| (Single | direction | | | | |
| crystal) | Reverse | 1.17 | 24.42 | 82.19 | 23.48 |
| | direction | | | | |
| 50 samples | | 1.12 ± | 23.81 ± | 78.85 ± | 21.06 ± |
| | | 0.04 | 0.36 | 1.57 | 1.27 |
| Comparative | Forward | 1.12 | 22.93 | 78.62 | 20.19 |
| Example 5 | direction | | | | |
| (Control | Reverse | 1.13 | 23.09 | 79.20 | 20.67 |
| sample) | direction | | | | |

| | | | | |
|---|---|---|---|---|
| 50 samples | 1.05 ± | 22.46 ± | 76.71 ± | 18.10 ± |
| | 0.04 | 0.39 | 1.53 | 1.21 |

FF: Fill factor = [maximum power point(Pₘₐₓ)/(J_{sc} × V_{oc})]
PCE: Power conversion efficiency = [(J_{sc} × V_{oc})/Pᵢₙ] × FF

Referring to Table 1, it can be confirmed that both the fill factor (FF) and power conversion efficiency (PCE) of the photovoltaic cell of Example 2 are higher than those of the photovoltaic cell of Comparative Example 5. Through this, when a photovoltaic cell is implemented using the crystal produced by the method according to Example 1, it can be inferred that the output energy for light energy incident from the sun is increased, and it can be inferred that the power generation quality is also increased.

FIG. 12C is short circuit current densities (J_{sc}, mA/cm²) of the photovoltaic cells prepared by methods of Example 2 and Comparative Example 5 according to light intensity (mW/cm²).

Referring to FIG. 12C, regarding the slope of the short circuit current density with respect to the light intensity, it can be confirmed that the calculated ideality factor of the photovoltaic cell according to Example 2 is 0.98, and the calculated ideality factor of the photovoltaic cell according to Comparative Example 5 is 1.03. It can be confirmed that the photovoltaic cells according to Example 2 and Comparative Example 5 are all close to the ideal value of 1.0 under the conditions of a short circuit current.

FIG. 12D is open-circuit voltages (V_{oc}, V) of the photovoltaic cells prepared by the methods of Example 2 and Comparative Example 5 according to light intensity (mW/cm²).

Referring to FIG. 12D, the photovoltaic cell according to Example 2 has a slope of the open circuit voltage with respect to the light intensity of 1.27 kT/q, and the photovoltaic cell according to Comparative Example 5 has a slope of the open circuit voltage with respect to the light intensity of 1.62 kT/q. Therefore, it can be confirmed that the photovoltaic cell according to Example 2 has lower non-radiative recombination than the photovoltaic cell according to Comparative Example 5.

FIG. 12E is electroluminescence external quantum efficiencies (EQE_{EL}) of a photovoltaic cell according to current densities. The electroluminescence external quantum efficiencies were measured by an integrated detection device including a 1-inch detector (891D-UV-5.3-CAL, Newport), a computer-controlled source measuring device (2611B, Keithley), and a spectrograph (USB 2000+, Ocean Optics).

Referring to FIG. 12E, when the current density is 20 mA/cm2, it can be confirmed that the photovoltaic cell according to Example 2 reaches an electroluminescence external quantum efficiency (EQE_{EL}) of 10.94%, whereas it can be confirmed that the photovoltaic cell according to Comparative Example 5 reaches an electroluminescence external quantum efficiency (EQE_{EL}) of 4.76%.

FIG. 12F is results of a space charge limited current (SCLC) analysis method of the photovoltaic cells prepared by the methods of Example 2 and Comparative Example 5. The space charge limited current analysis method is a method of analyzing how current flows when a voltage is applied to the space between electrodes.

Referring to FIG. 12F, the photovoltaic cell according to Example 2 has a trap charge limited current (TCLC) of 0.66 V, and a trap density corresponding thereto is 1.68×10¹⁶ cm⁻³. The photovoltaic cell according to Comparative Example 5 has a trap charge limited current of 0.75 V, and a trap density corresponding thereto is 1.93×10¹³ cm⁻³.

Hereinabove, the preferred embodiments of the present disclosure have been described in detail, but the scope of rights of the present disclosure is not limited thereto, and various modifications and improved forms made by those skilled in the art using the basic concept of the present disclosure defined in the following claims also fall within the scope of the right of present disclosure.

What is claimed is:

1. A method for preparing a perovskite crystal, the method comprising:
a step S1 of preparing a perovskite solution containing a perovskite precursor and a first polar aprotic solvent; and
a step S2 of preparing a perovskite crystal by mixing the perovskite solution and an antisolvent,
wherein the antisolvent includes a second polar aprotic solvent.

2. The method of claim 1, wherein the first polar aprotic solvent has a dielectric constant of 32 to 40 and a relative polarity of 0.35 to 0.45 based on water having a relative polarity of 1.0.

3. The method of claim 2, wherein the first polar aprotic solvent includes dimethylformamide (DMF).

4. The method of claim 1, wherein the antisolvent has a dielectric constant of 16 or more.

5. The method of claim 4, wherein the antisolvent has a dielectric constant of 24 or more.

6. The method of claim 5, wherein the antisolvent has a dielectric constant of 28 or more.

7. The method of claim 6, wherein the antisolvent has a dielectric constant of 32 to 40.

8. The method of claim 7, wherein the antisolvent has a relative polarity of more than 0.4 and 0.6 or less based on water having a relative polarity of 1.0.

9. The method of claim 8, wherein the antisolvent has a relative polarity of more than 0.4 and 0.5 or less based on water having a relative polarity of 1.0.

10. The method of claim 1, wherein the antisolvent includes acetonitrile (CH₃CN).

11. The method of claim 1, wherein the perovskite crystal is a compound represented by the following General Formula 1:
AₐB_{b}X_{c} [General Formula 1]
in General Formula 1,
A is a monovalent organic cation or a monovalent metal cation,
B is a divalent or trivalent metal cation,
X is a monovalent anion, and
a, b, and c are all natural numbers, and satisfy a+2b=c or a+3b=4c.

12. The method of claim 11, wherein the perovskite crystal is δ-FAPbI₃.

13. A perovskite crystal prepared by the method for preparing a perovskite crystal according to claim 1.

14. The perovskite crystal of claim 13, wherein the perovskite crystal is a single crystal of a delta phase (δ-Phase).

15. A light absorption layer made of the perovskite crystal according to claim 13.

16. A photovoltaic cell comprising:
a first electrode;
a second electrode; and
the light absorption layer according to claim 15 disposed between the first electrode and the second electrode.

17. The photovoltaic cell of claim 16, further comprising:
a hole transport layer disposed between the first electrode and the light absorption layer; and
an electron transport layer disposed between the second electrode and the light absorption layer.

18. The photovoltaic cell of claim 17, further comprising: a hole blocking layer disposed between the second electrode and the electron transport layer.
